(19) United States
(12) Patent Application Publication
(10) Pub. No.: US 2026/0032887 A1
(43) Pub. Date: Jan. 29, 2026

(54) Memory Circuitry And Methods Used In Forming Memory Circuitry

(71) Applicant: Micron Technology, Inc., Boise, ID (US)

(72) Inventors: Kamal M. Karda, Boise, ID (US); Aniket Gupta, Boise, ID (US); Si-Woo Lee, Saratoga, CA (US); David Daycock, Boise, ID (US); Albert Liao, Boise, ID (US); Matthew Jerry, Boise, ID (US); Haitao Liu, Boise, ID (US); Cheng Li, Boise, ID (US); Ninad Chamele, Boise, ID (US)

(73) Assignee: Micron Technology, Inc., Boise, ID (US)

(21) Appl. No.: 19/231,949

(22) Filed: Jun. 9, 2025

Related U.S. Application Data
(60) Provisional application No. 63/676,216, filed on Jul. 26, 2024.

(51) Int. Cl. H10B 12/00

(52) U.S. Cl. CPC H10B 12/482; H10B 12/02

(57) ABSTRACT

Memory circuitry comprises digitlines extending vertically through vertically-alternating insulative tiers and memory-cell tiers in trenches that extend horizontally along the first direction. The digitlines comprise pairs thereof in individual of the trenches. The pairs in the individual trenches are spaced from one another in the first direction. The digitlines in individual of the pairs are spaced from one another in the second direction on opposite second-direction sides of the individual trenches in a horizontal cross-section. At least one of (a) and (b) is provided, where (a): a vertically-elongated void-space in the individual trenches between immediately-first-direction-adjacent of the pairs, or (b): the individual digitlines in the first direction being wider at their bottoms than at their tops. Methods are disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

Memory cells may be arranged or arrayed in several manners including, for example, in a vertical stack (e.g., along a z direction) comprising a three-dimensional (3D) memory array region having horizontal tiers in which individual memory cells are received (e.g., arrayed in x and y directions). The stack in the 3D memory array region comprises vertically-alternating insulative tiers and conductive tiers (e.g., as part of memory-cell tiers) that extend into a stair-step region. The stair-step region includes individual “stairs” (alternately termed “steps” or “stair-steps”) that define contact regions of conductive lines of individual of the conductive tiers to which vertical conductive vias can contact to provide electrical access to/from those conductive lines.

### BRIEF DESCRIPTION OF THE DRAWINGS

FIG. 1 is a diagrammatic schematic of a DRAM memory array and peripheral circuitry in accordance with the prior art and in accordance with an embodiment of the invention.

FIG. 2 is an enlargement of a portion of FIG. 1.

FIGS. 3-9 are diagrammatic sectional views of a construction in process in accordance with embodiments of the invention.

FIGS. 10-38 are diagrammatic sequential sectional and/or enlarged views of the construction of FIGS. 3-9, or portions thereof or alternate and/or additional embodiments, in process in accordance with some embodiments of the invention.

### DETAILED DESCRIPTION OF EXAMPLE EMBODIMENTS

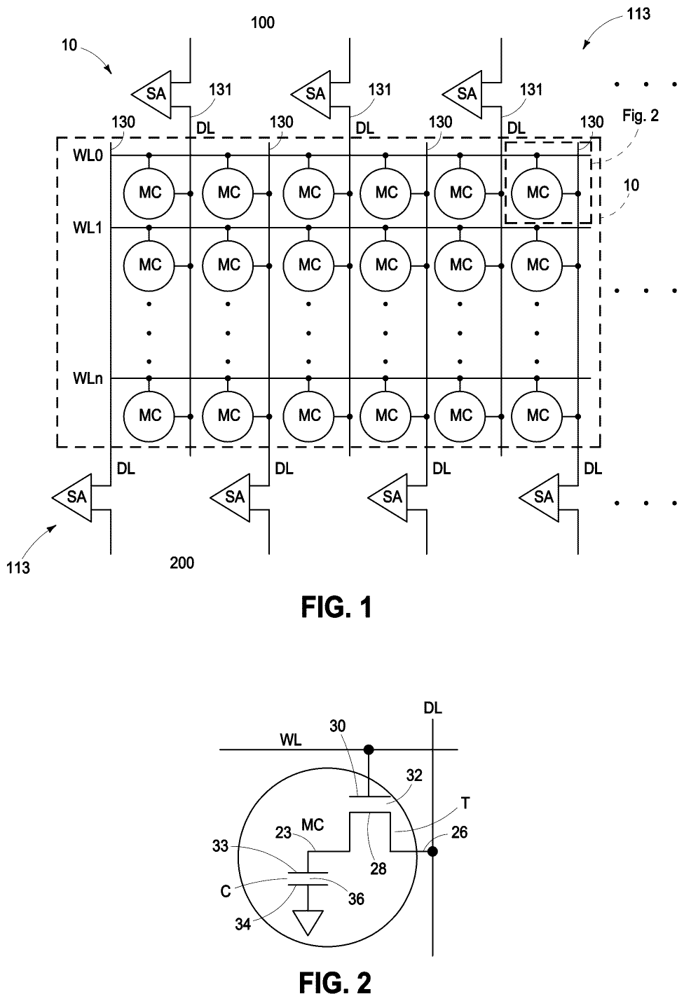

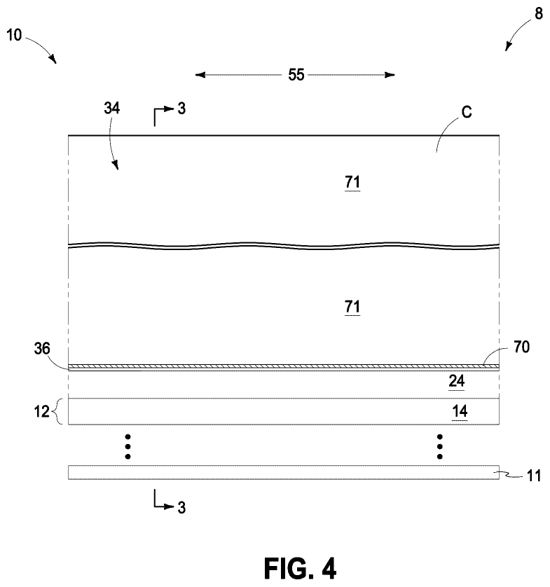

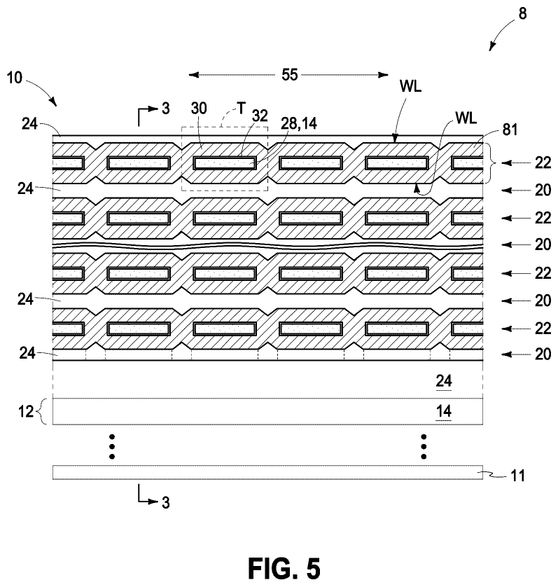

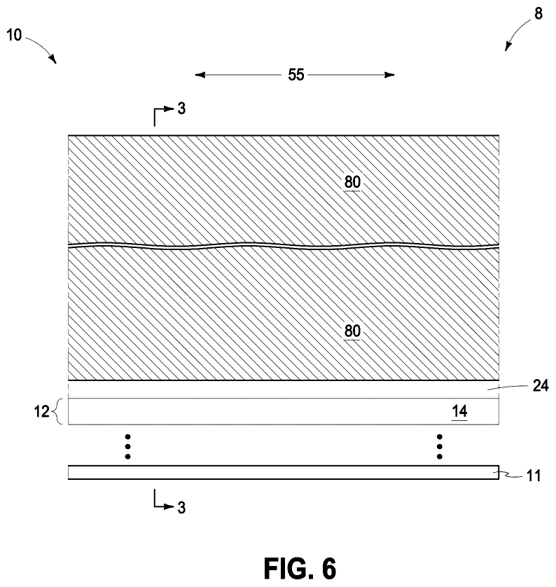

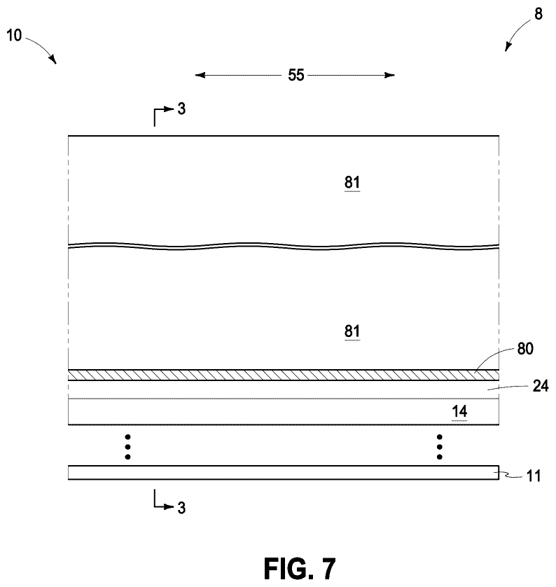

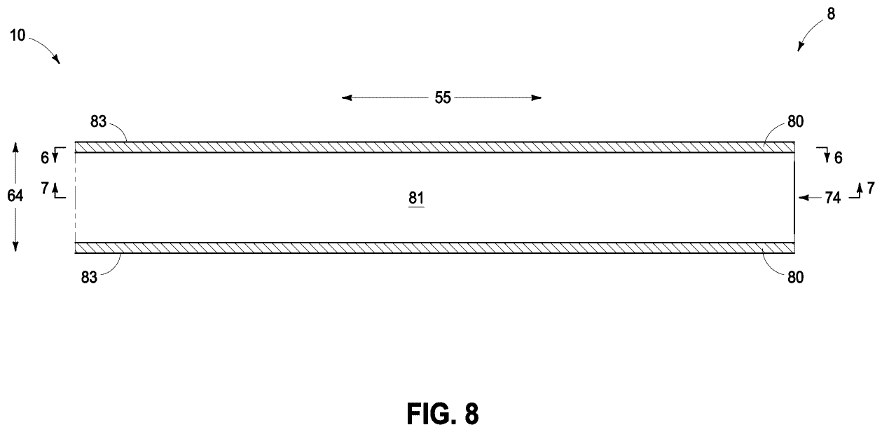

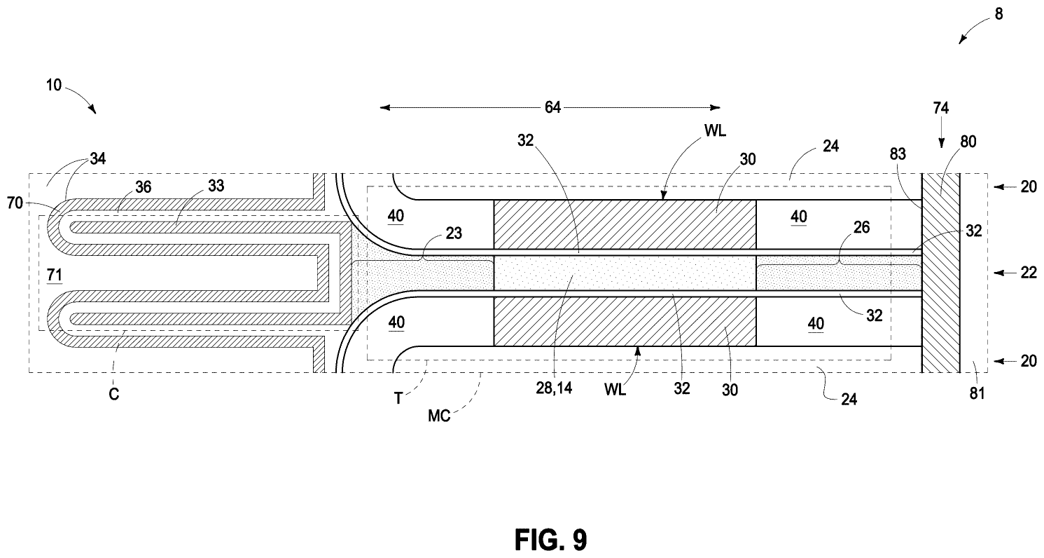

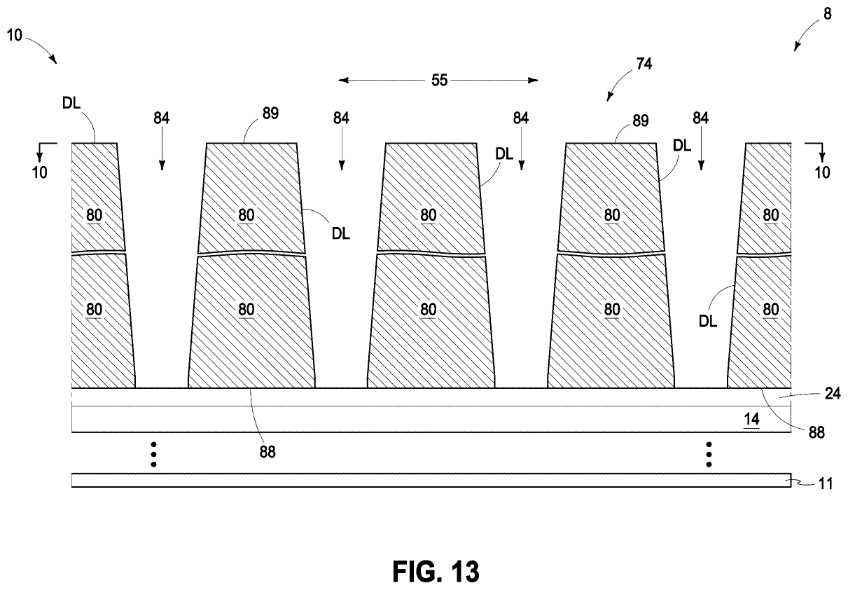

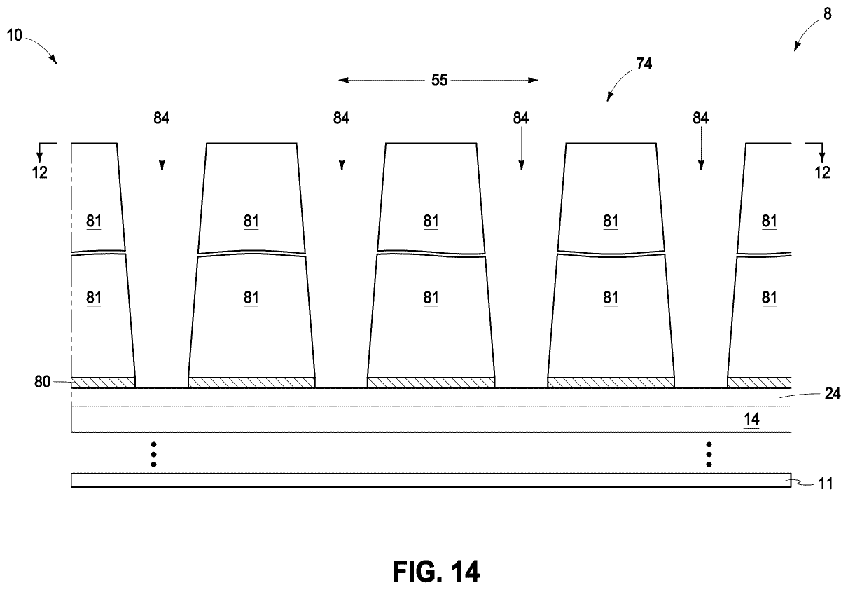

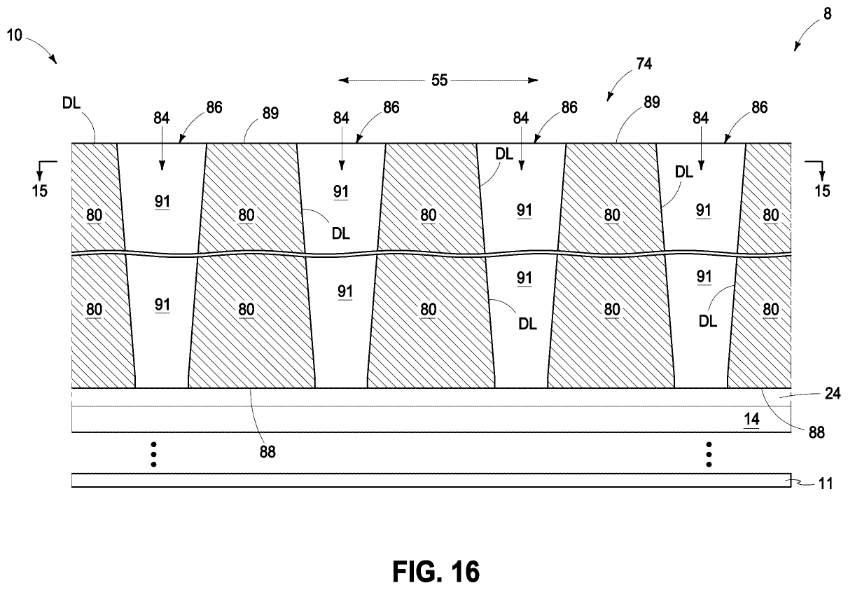

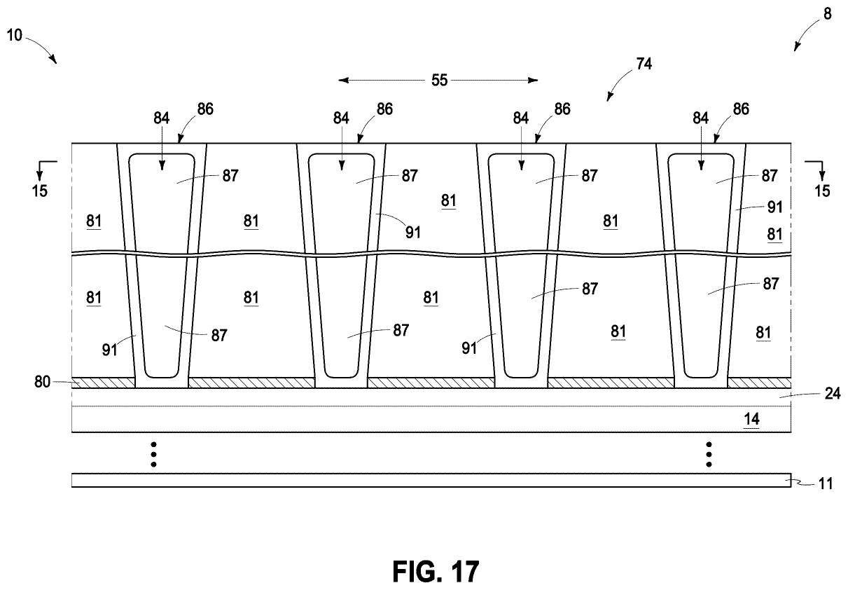

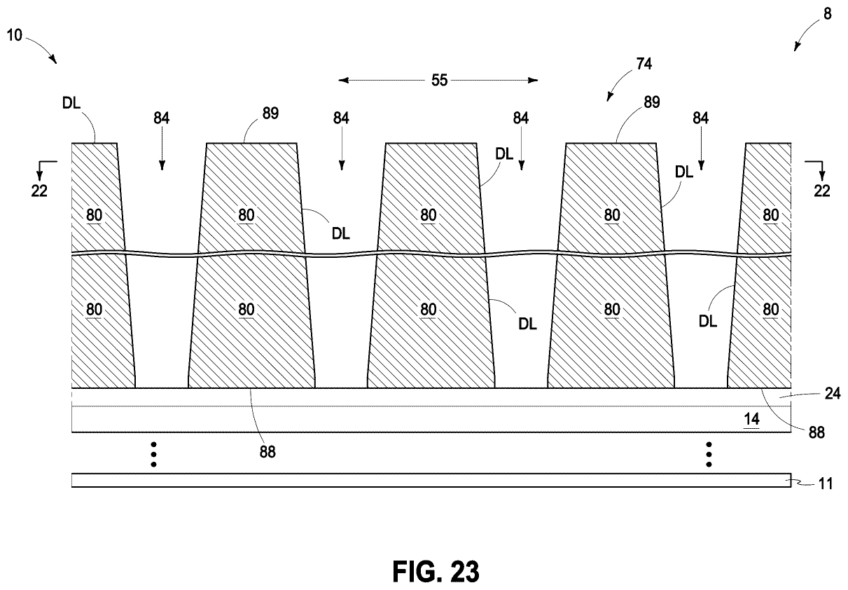

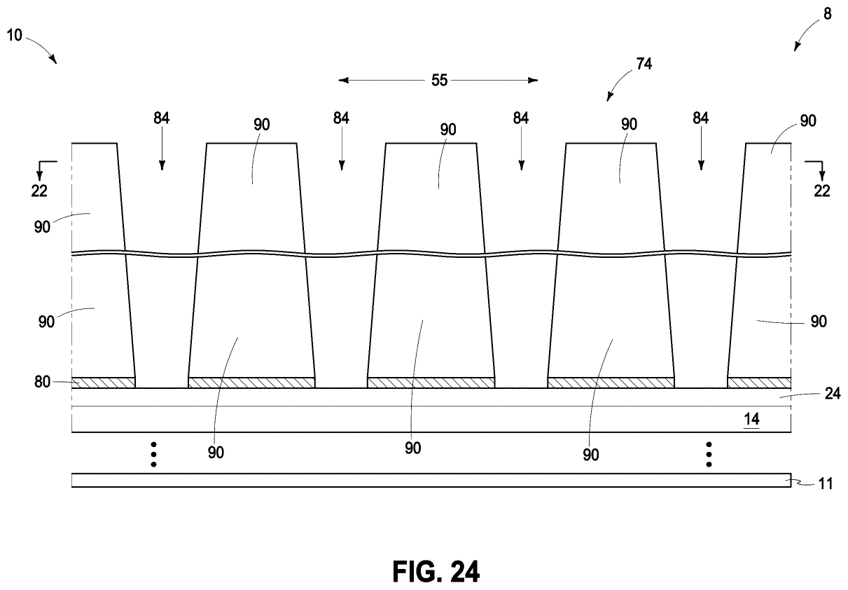

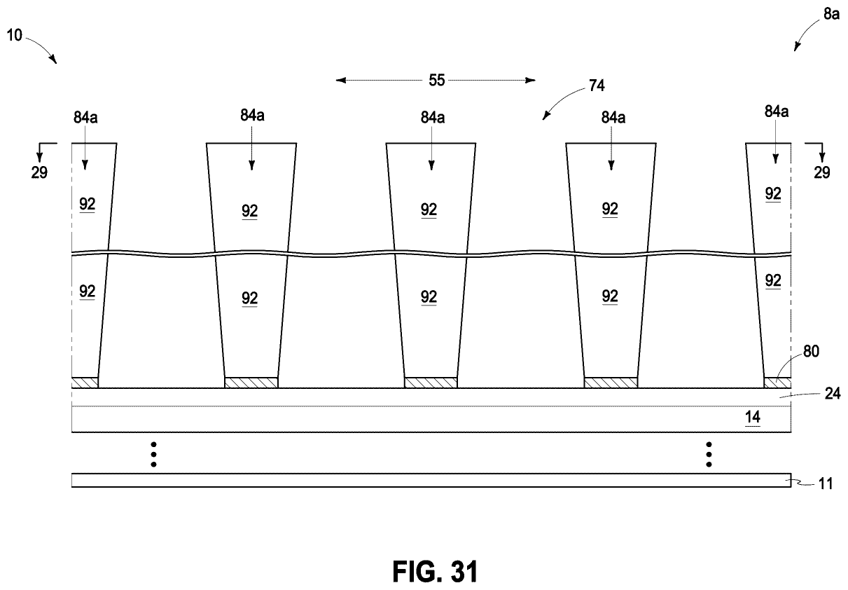

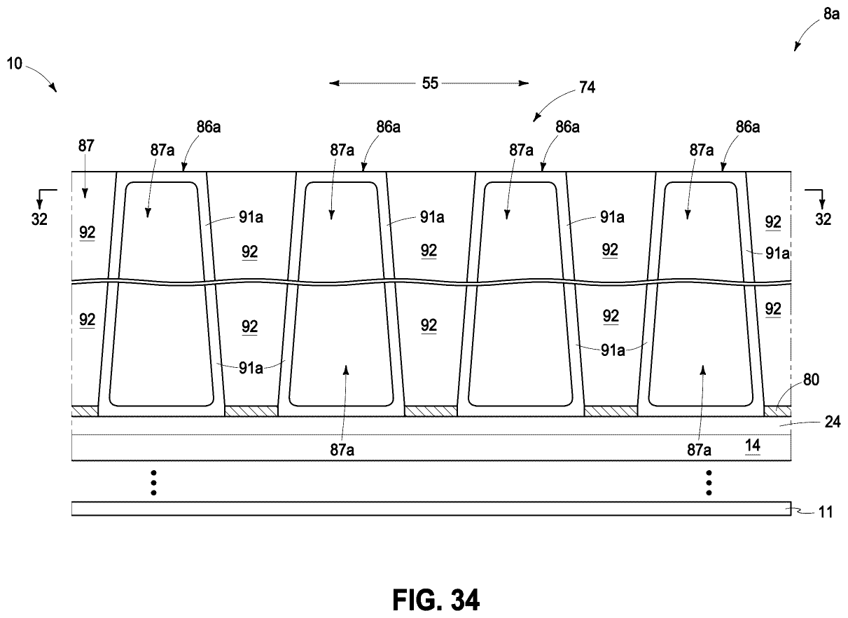

Embodiments of the invention encompass memory circuitry (e.g., DRAM) having vertically-alternating tiers of insulative material and memory cells, with the memory cells individually comprising a capacitor and a horizontally-oriented transistor. Embodiments of the invention also encompass methods used in forming such memory circuitry. Example method embodiments are first described with reference to FIGS. 1-38.

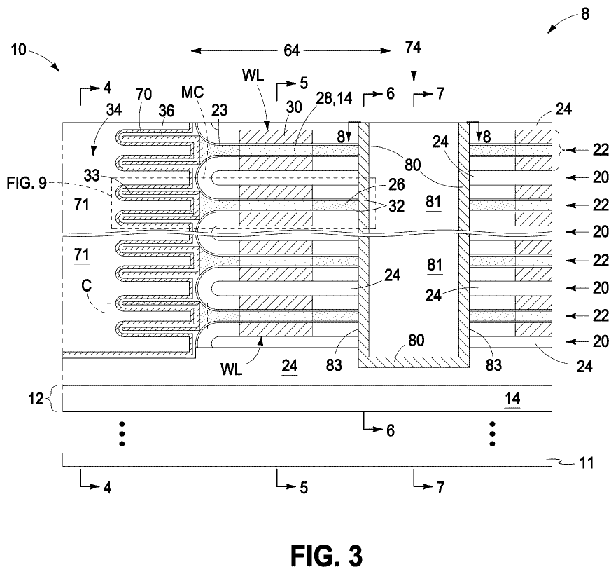

One example prior art schematic diagram of DRAM circuitry, and in accordance with an embodiment of the invention, is shown in FIGS. 1 and 2. FIG. 2 shows example memory cells MC individually comprising a transistor T and a capacitor C. One electrode of capacitor C is directly electrically coupled to a suitable potential (e.g., ground) and the other capacitor electrode is contacted with or comprises one of the source/drain regions of transistor T. The other source/drain region of transistor T is directly electrically coupled with a digitline/sense line 130 or 131 (also individually designated as DL). The gate of transistor T is directly electrically coupled with (e.g., comprises part of) a wordline/access line WL. FIG. 1 shows digitlines 130 and 131 extending from one of opposite sides 100 and 200 of a memory array area 10 into a peripheral circuitry area 113 that is aside memory array area 10. Digitlines 130 and 131 individually directly electrically couple with a sense amp SA on opposite sides 100 and 200 of array area 10 within peripheral circuitry area 113. Sense amps SA could be on only one side or all directly above or directly below memory array area 10. Non-schematic structure embodiments as shown herein in FIGS. 3+ have the wordlines/access lines running horizontally and the digitlines/sense lines running vertically.

Referring to FIGS. 3-9, an example fragment of a substrate construction 8 comprising array or array area 10 has been fabricated relative to a base substrate 11. Substrate 11 may comprise any one or more of conductive/conductor/conducting, semiconductive/semiconductor/semiconducting, and insulative/insulator/insulating (i.e., electrically herein) materials. Materials may be aside, elevationally inward, or elevationally outward of the FIGS. 3-9-depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array.

Semiconductor material 12 is above base substrate 11. In one embodiment, semiconductor material 12 comprises silicon material 14 (e.g., elemental monocrystalline or polycrystalline silicon and which may include one or more additional elements). If, by way of example, base substrate 11 is bulk monocrystalline silicon, silicon material 14 may be an upper or uppermost portion of such bulk monocrystalline silicon.

Vertically-alternating insulative tiers 20 and memory-cell tiers 22 have been formed above semiconductor material 12. Example memory-cell tiers 22 comprise memory cells MC and example insulative tiers 20 comprise insulative material 24 (e.g., silicon dioxide). Memory cells MC individually comprise a horizontal transistor T comprising a gate 30 (e.g., conductive metal material) that is part of one of a plurality of horizontal conductive access lines WL that individually directly electrically couple together multiple of gates 30 of different ones of horizontal transistors T that are in the same memory-cell tier 22. Access lines WL extend horizontally along a first direction 55 and are laterally spaced from one another in a second direction 64 that is orthogonal to the first direction.

Example horizontal transistors T also comprise a first source/drain region 23, a second source/drain region 26, and a channel region 28 horizontally between the first and second source/drain regions. Regions 23, 26, and 28 of different immediately-horizontally-adjacent memory cells MC into and out of the plane of the page upon which FIG. 3 lies in a common memory-cell tier 22 may be isolated relative one another by insulative material (not shown). Gates 30 have a gate insulator 32 (e.g., dielectric or ferroelectric) between at least channel region 28 and gate 30 (e.g., gate-all-around the channel). An example insulator material 40 (e.g., silicon nitride) is laterally against lateral sides/edges of gates 30. Example memory cells MC also comprise a capacitor C having a first capacitor electrode 33 (e.g., a storage-node electrode), a second capacitor electrode 34 (e.g., comprising conductive metal material 70 and conductively-doped polysilicon 71), and a capacitor insulator 36 there-between (e.g., dielectric or ferroelectric). Second capacitor electrodes 34 of multiple capacitors C are directly electrically coupled with one another. First capacitor electrode 33 is directly coupled to first source/drain region 23 of transistor T.

Example capacitors C and example horizontal transistors T are shown as already having been formed, although any of such could be formed later in processing not material to aspects of the inventions disclosed herein. Regardless, example manners not material to the inventions disclosed herein in forming that which is shown are, for example, shown in Micron Technology's U.S. Patent Application Publication Nos. 2022/0254784, 2022/0130834, U.S. Pat. No. 11,342,218, etc.

Trenches 74 extend through vertically-alternating tiers 20 and 22. Trenches 74 extend horizontally along first direction 55 and are spaced relative one another in second direction 64 (only one trench being shown for brevity). Trenches 74 individually comprise conductive material 80 (e.g., conductive metal material) and sacrificial material 81 (in some embodiments referred to as first sacrificial material 81; e.g., carbon). Conductive material 80 and sacrificial material 81 in individual trenches 74 extend through vertically-alternating tiers 20 and 22 and extend horizontally in first direction 55. Conductive material 80 is on opposite second-direction sides 83 of individual trenches 74 and sacrificial material 81 is laterally there-between. Conductive material 80 may connect and continuously span across bottoms of trenches 74 in second direction 64, as shown.

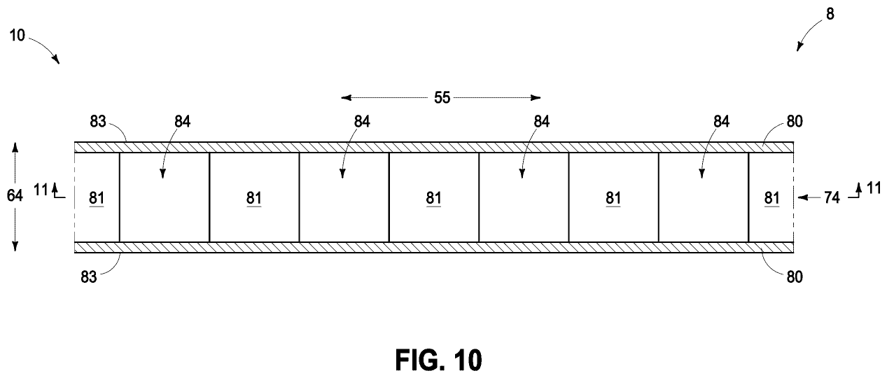

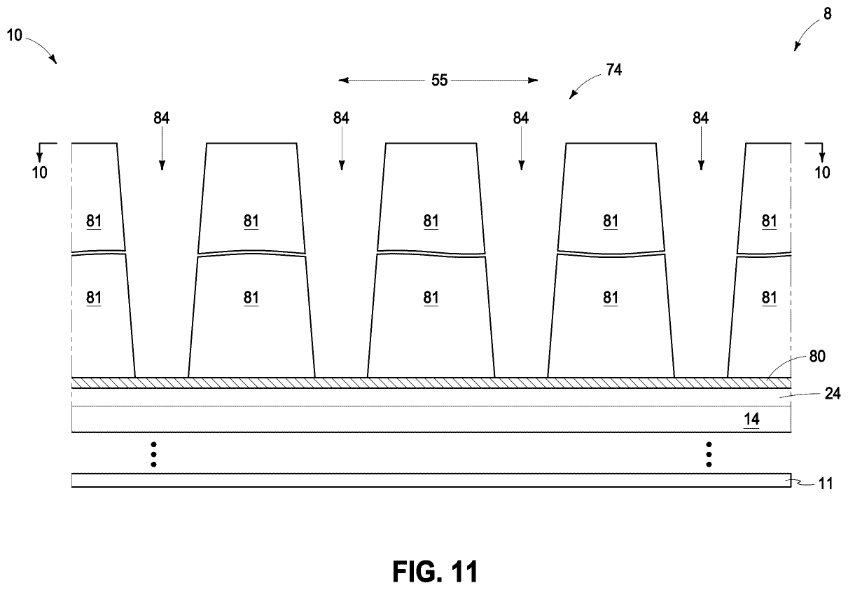

Referring to FIGS. 10 and 11, openings 84 having been formed through sacrificial material 81 (e.g., by photolithographic patterning and etch) in individual trenches 74 and that are spaced relative one another in first direction 55 and laterally-expose conductive material 80 on second-direction sides 83 of individual trenches 74. Openings 84 taper inwardly moving deeper into construction 8 (as shown in first direction 55; such may also occur in section direction 64 but is not visible in that which is depicted by FIGS. 10 and 11 and is not shown in other drawings).

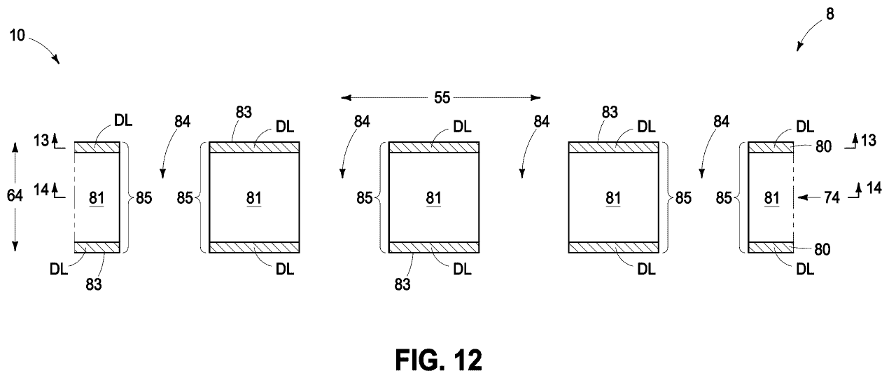

Referring to FIGS. 12-14, through openings 84, some of conductive material 80 on second-direction sides 83 of individual trenches 74 has been removed (e.g., by etching) to form pairs 85 of digitlines DL from remaining conductive material 80. Pairs 85 in individual trenches 74 are spaced from one another in first direction 55. Digitlines DL in individual pairs 85 are spaced from one another in second direction 64 on opposite second-direction sides 83 of individual trenches 74 in a horizontal cross-section (e.g., in the depicted example, any horizontal cross-section taken above where conductive material 80 connects in the bottom of trenches 74). In one embodiment and as shown, individual digitlines DL in first direction 55 (at least) are wider at their bottoms 88 than at their tops 89 (e.g., due to openings 84 being narrower in first direction 55). Digitlines DL in second direction 64 may also be wider at their bottoms 88 than at their tops 89. Individual second source/drain regions 26 of individual horizontal transistors T that are in different memory-cell tiers 22 are directly electrically coupled to individual digitlines DL.

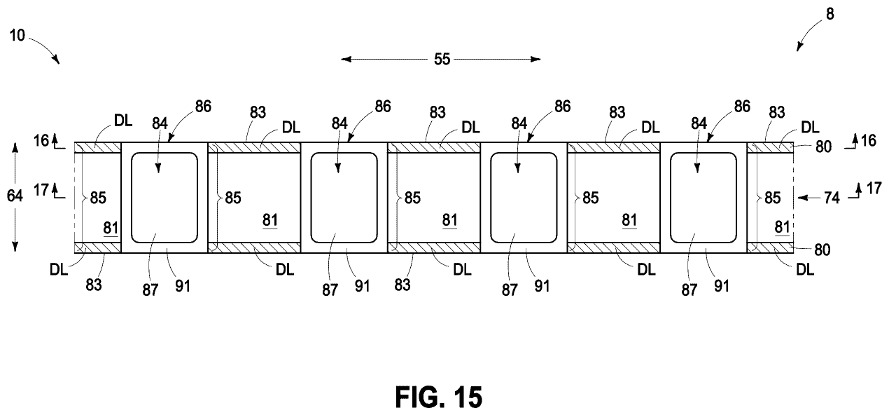

Referring to FIGS. 15-17, a frustum 86 (e.g., comprising solid material 91), having a vertically-elongated void-space 87, is formed in individual openings 84 through vertically-alternating tiers 20 and 22 (e.g., by chemical vapor deposition, and which may occlude void-space 87 at its top and has been planarized back [e.g., CMP] as shown). Frustum 86 may be any of insulative, conductive, or semiconductive. In one embodiment, frustum 86 is insulative (e.g., comprising silicon dioxide and/or silicon nitride) and remains in a finished-circuitry construction.

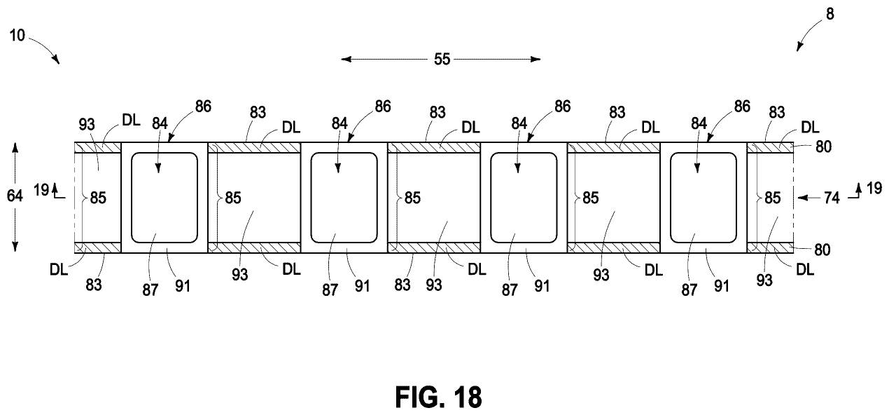

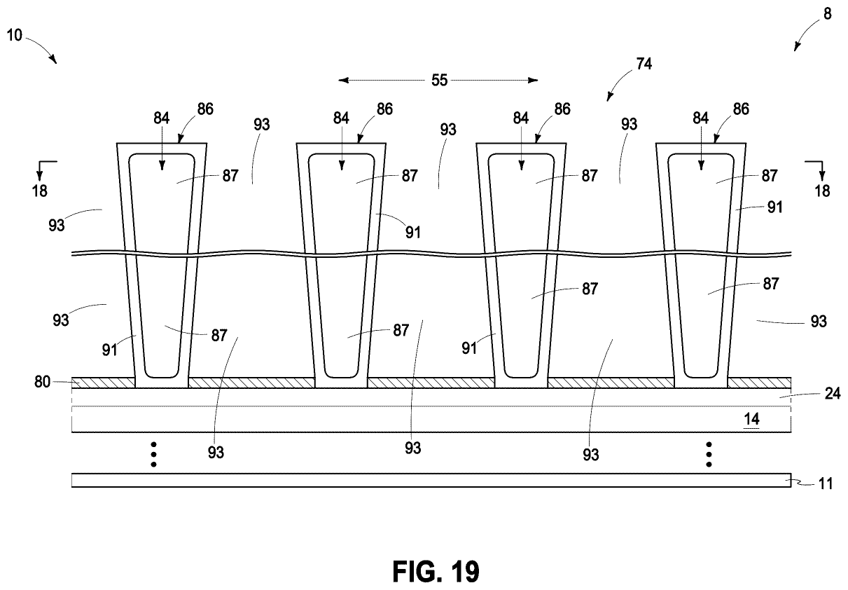

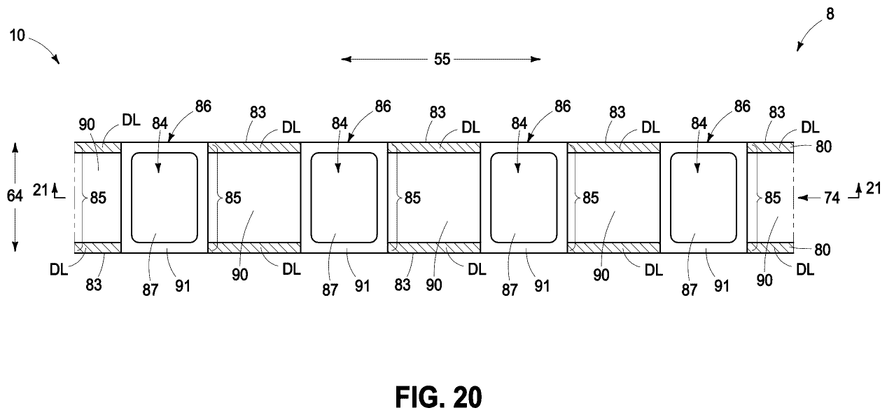

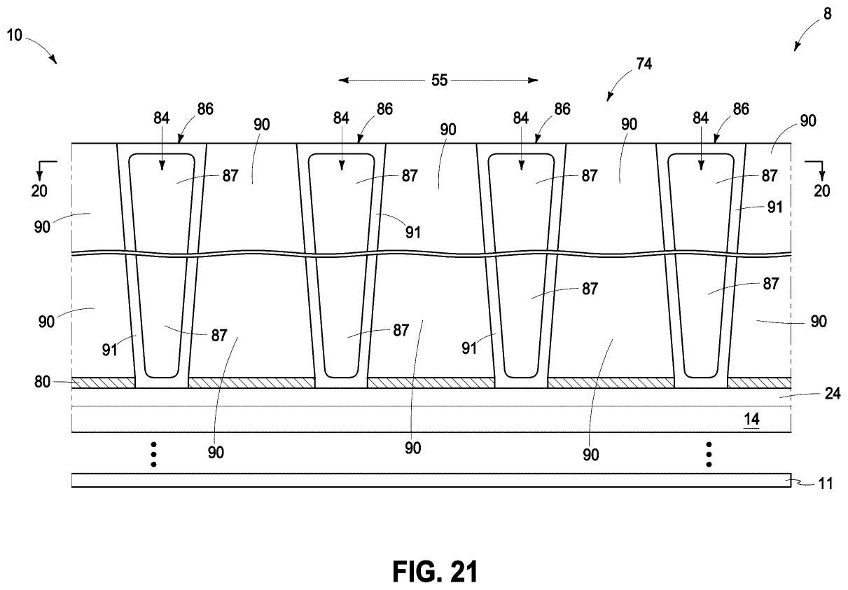

Referring to FIGS. 18-21, sacrificial material 81 (no longer shown) has been removed (e.g., by etching) selectively relative to frustum 86 (FIGS. 18 and 19; e.g., leaving a void-space 93) and has been replaced with insulator material 90 (FIGS. 20 and 21; e.g., silicon dioxide and/or silicon nitride). In one embodiment where frustum 86 is insulative, such may be of the same composition as that of insulator material 90 and in another embodiment may be of a different composition from that of insulator material 90. A selective conductive-material deposition may be conducted after the processing shown by FIGS. 18 and 19 and before the processing shown by FIGS. 20 and 21 to laterally thicken digitlines DL if desired (not shown). Ideally where frustums 86/void-spaces 87 are occluded at their tops by solid frustum material 91 as shown, insulator material 90 is prevented from depositing into void-space left by the removal of sacrificial material 81. Alternately, if not so occluded and considerably less desirable, an additional masking step could be used either before or after the processing shown by FIGS. 20 and 21 such that insulator material 90 does not fill void-spaces 87.

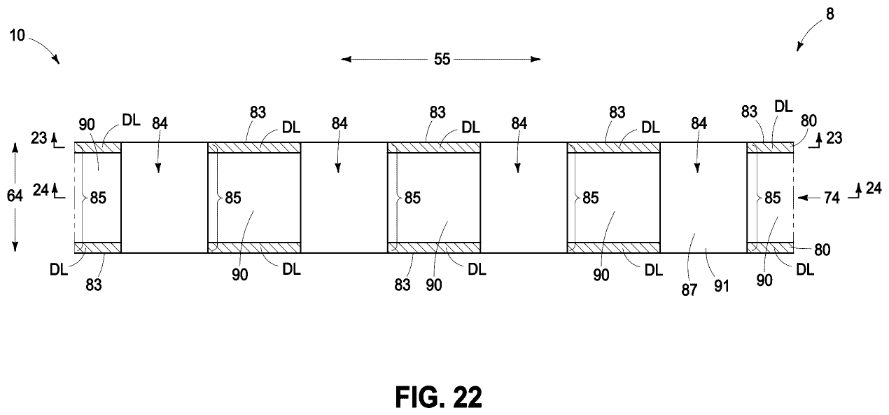

In one embodiment, for example as shown in FIGS. 22-24, frustums 86 (no longer shown) have been removed (e.g., by etching) after replacing sacrificial material 81 with insulator material 90. Alternately, frustums 86 may remain as shown in FIGS. 20 and 21. Accordingly, frustums 86 may remain or may not remain in the finished-circuitry construction. In one such latter embodiment, frustums 86 are insulative and insulative material thereof is of the same composition as insulator material 90, with the removing comprising a timed non-selective etch of insulative frustums 86 relative to insulator material 90. In an alternate such embodiment, frustums 86 are of different composition from that of insulator material 90 and the removing comprises a selective etch of frustums 86 relative to insulator material 90. Regardless, void-space left by the removal of frustums 86 may be subsequently wholly or partially filled with solid insulating material (not shown), or not.

Any other attribute(s) or aspect(s) as shown and/or described herein with respect to other embodiments may be used in the embodiments shown and described with reference to the above embodiments.

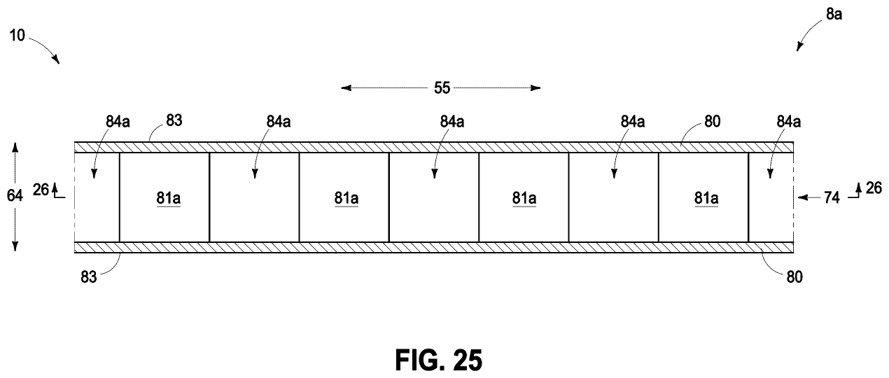

An alternate example method embodiment to those described above is described with reference to FIGS. 25-38 with respect to an alternate construction 8a. Like numerals from the above-described embodiments have been used where appropriate, with some construction differences being indicated with the suffix “a” or with different numerals.

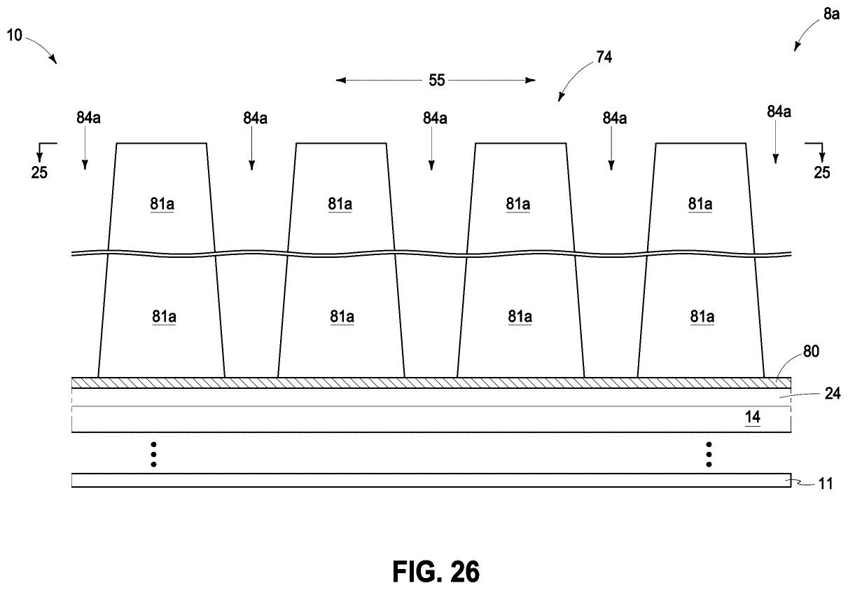

Referring to FIGS. 25 and 26, such are analogous to FIGS. 10 and 11. However, openings 84a as formed through first sacrificial material 81a are positioned differently than openings 84 are in FIGS. 10 and 11.

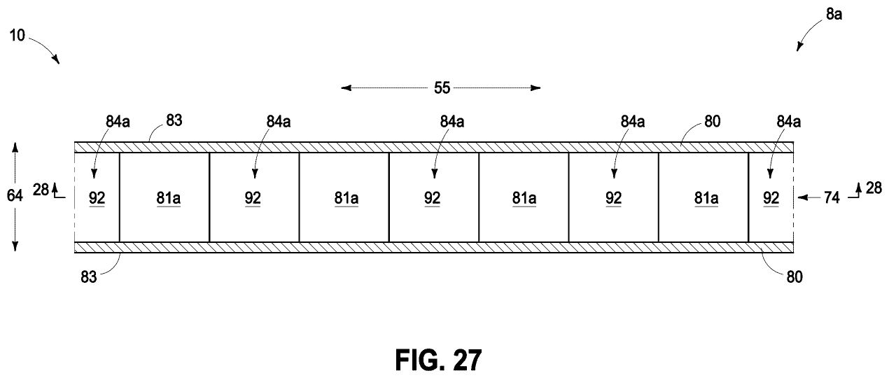

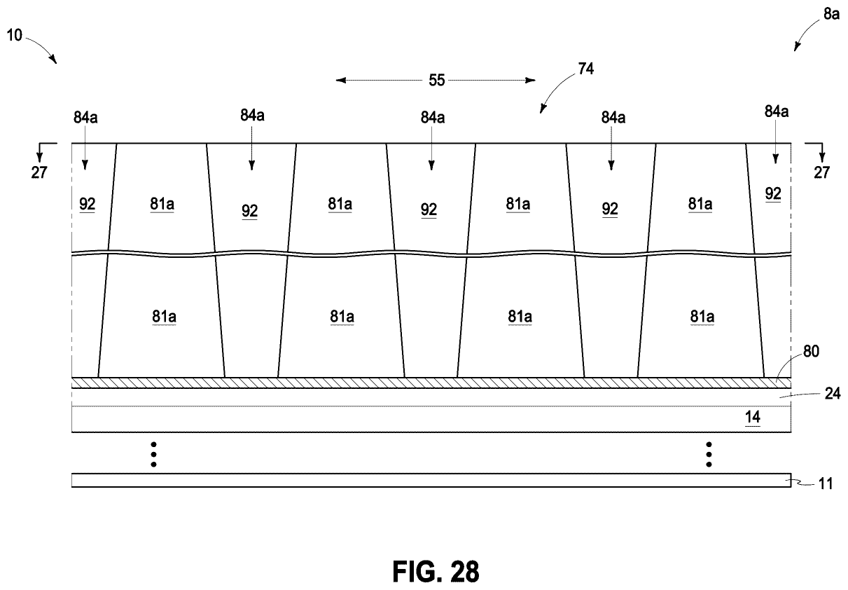

Referring to FIGS. 27 and 28, second sacrificial material 92 has been formed in openings 84a. Second sacrificial material 92 is of different composition (e.g., silicon nitride) from that of first sacrificial material 81a. Sacrificial materials 81, 81a, and 92 may be any of insulative, conductive, or semiconductive, yet of a composition that enables selective removal (e.g., by etching) thereof relative to other materials that are laterally-adjacent thereto as shown in various of the figures.

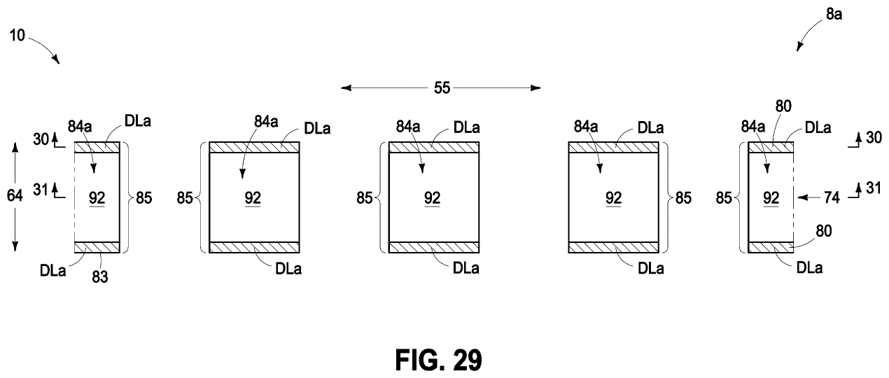

Referring to FIGS. 29-31, and somewhat analogous to FIGS. 12-14, first sacrificial material 81a (no longer shown) and some of conductive material 80 on second-direction sides 83 of individual trenches 74 have been removed (e.g., by etchings) to form pairs 85 of digitlines DLa from remaining conductive material 80. Digitlines DLa in individual pairs 85 have second sacrificial material 92 there-between in a horizontal cross-section (e.g., in the depicted example, any horizontal cross-section taken above where conductive material 80 connects in the bottom of trenches 74).

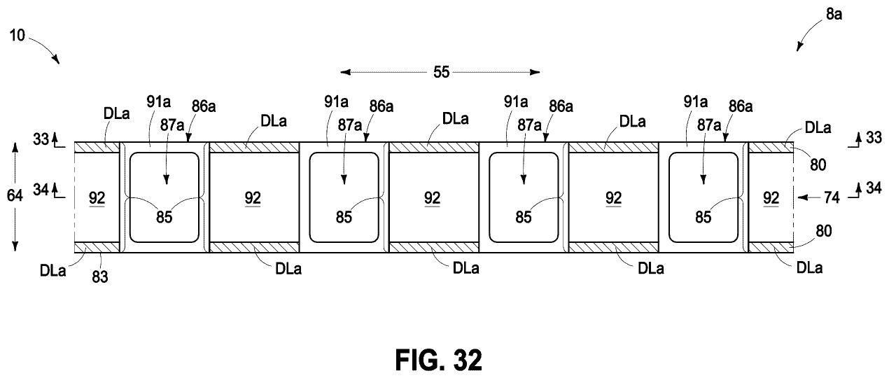

Referring to FIGS. 32-34, and analogous to FIGS. 15-17, a frustum 86a, (e.g., comprising solid material 91a) having a vertically-elongated void-space 87a therein, has been formed between immediately-first-direction-adjacent of pairs 85 in individual trenches 74 (there being no other pair 85 between those that are immediately-first-direction-adjacent one another). Frustums 86a may of course have any of the attributes described above with respect to frustums 86.

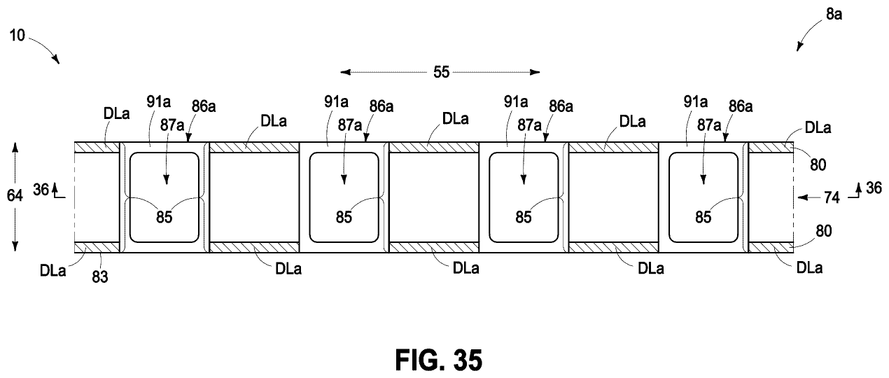

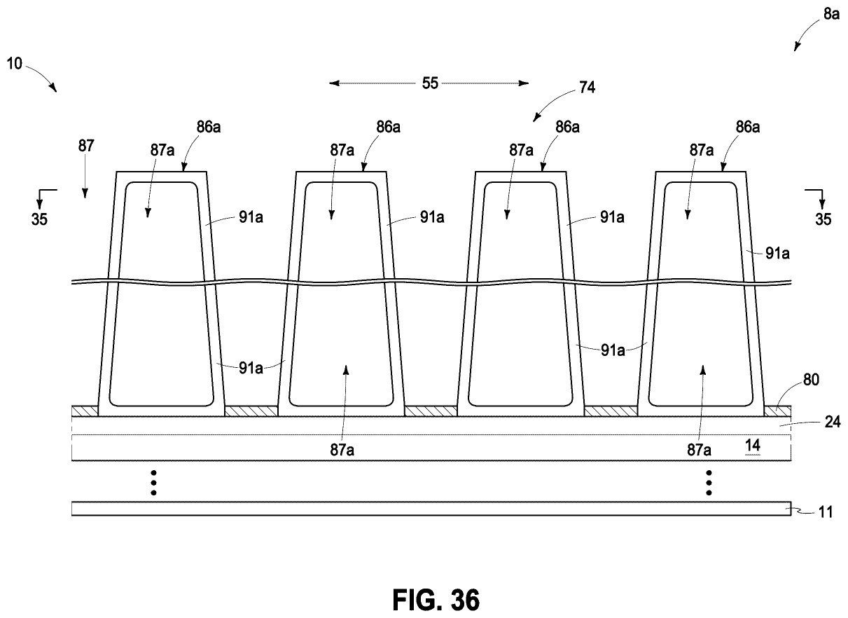

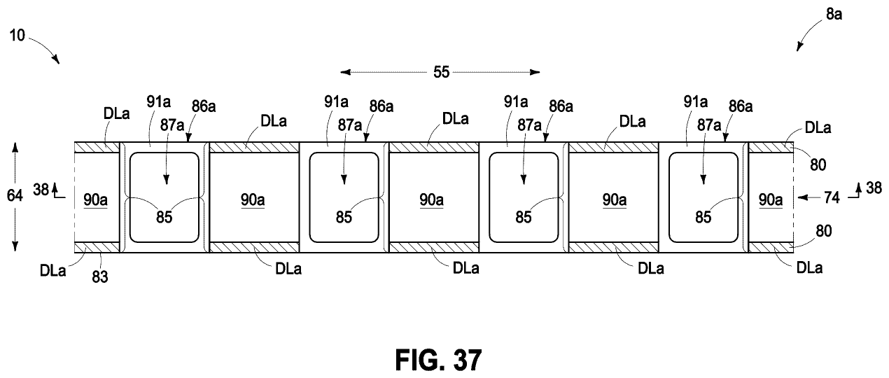

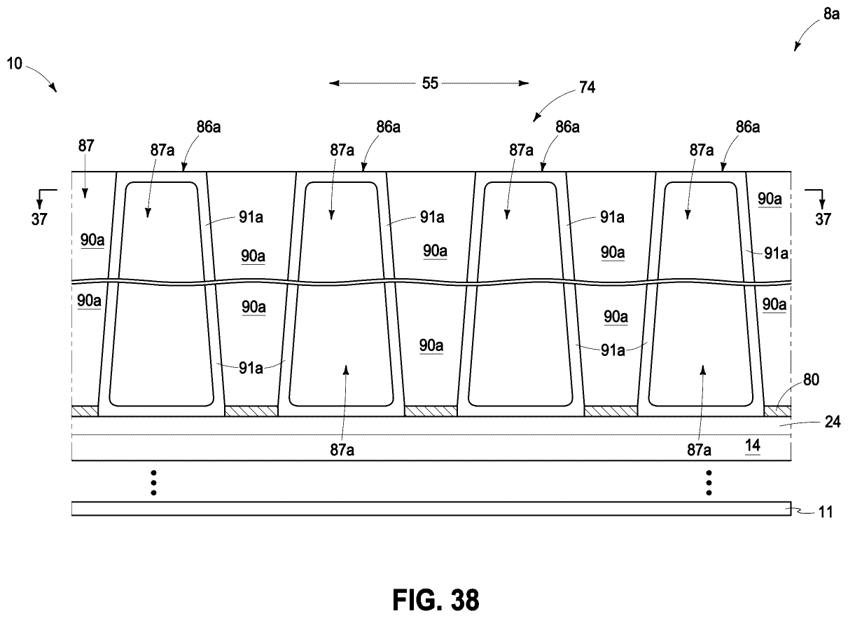

Referring to FIGS. 35-38, and analogous to FIGS. 18-21, second sacrificial material 92 (no longer shown) has been removed (e.g., by etching) selectively relative to frustum 86a (FIGS. 35 and 36) and has been replaced with insulator material 90a (FIGS. 37 and 38).

Any other attribute(s) or aspect(s) as shown and/or described herein with respect to other embodiments may be used.

Alternate embodiment constructions may result from method embodiments described above, or otherwise. Regardless, embodiments of the invention circuitry independent of method of manufacture. Nevertheless, such circuitry arrays may have any of the attributes as described herein in method embodiments. Likewise, the above-described method embodiments may incorporate, form, and/or have any of the attributes described with respect to device embodiments.

In one embodiment, memory circuitry (e.g., 8, 8a) comprises memory cells (e.g., MC) and vertically-alternating insulative tiers (e.g., 20) and memory-cell tiers (e.g., 22). The memory cells individually comprise a horizontal transistor (e.g., T) comprising a gate (e.g., 30) that is part of one of a plurality of horizontal conductive access lines (e.g., WL) that individually directly electrically couple together multiple of the gates of different ones of the horizontal transistors that are in the same memory-cell tier. The access lines extend horizontally along a first direction (e.g., 55) and are laterally spaced from one another in a second direction (e.g., 64) that is orthogonal to the first direction. Digitlines (e.g., DL, DLa) extend vertically through the vertically-alternating insulative tiers and memory-cell tiers in trenches (e.g., 74) that extend horizontally along the first direction. Individual source/drain regions (e.g., 26) of individual of the horizontal transistors that are in different memory-cell tiers are directly electrically coupled to individual of the digitlines. The digitlines comprise pairs (e.g., 85) thereof in individual of the trenches. The pairs in the individual trenches are spaced from one another in the first direction. The digitlines in individual of the pairs are spaced from one another in the second direction on opposite second-direction sides (e.g., 83) of the individual trenches in a horizontal cross-section. The memory circuitry comprises at least one of (a) and (b), where:
(a): a vertically-elongated void-space (e.g., 87, 87a) in the individual trenches between immediately-first-direction-adjacent of the pairs; or
(b): the individual digitlines in the first direction being wider at their bottoms (e.g., 88) than at their tops (e.g., 89).

In one embodiment, the memory circuitry comprises the (a). In one such embodiment, solid insulative material (e.g., 91, 91a) completely encircles the void-space in a horizontal cross-section. In one such latter embodiment, the solid insulative material comprises a frustum (e.g., 86, 86a) that completely encircles the vertical void-space completely vertically through the vertically-alternating insulative tiers and memory-cell tiers. In another such latter embodiment, for example as shown in FIGS. 22-24, the void-space is directly against conductive material of immediately-first-direction-adjacent of the pairs (e.g., individual openings 84 form a vertically-elongated void-space that is directly against conductive material 80 of digitlines DL of individual pairs 85; e.g., the same would apply with respect to construction 8a in FIGS. 37 and 38 if frustums 86a were subsequently removed [not shown]).

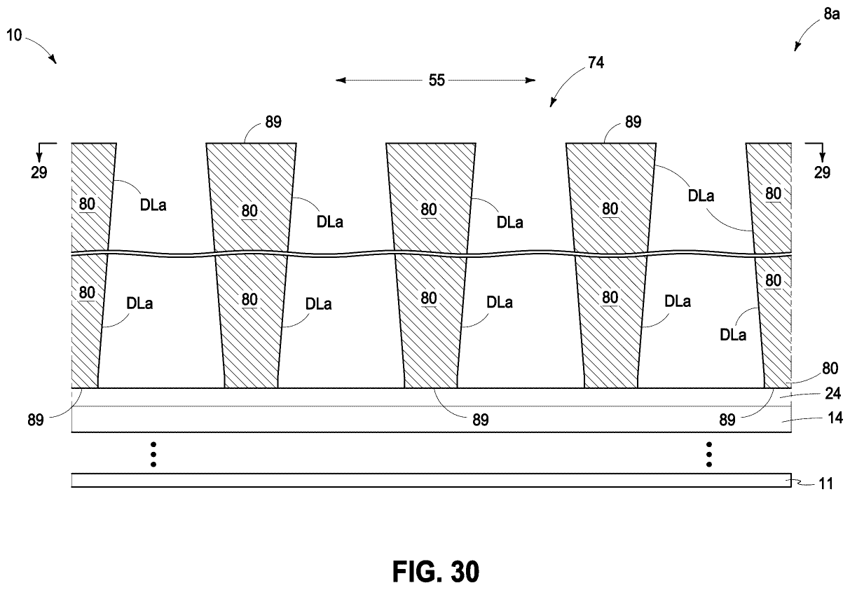

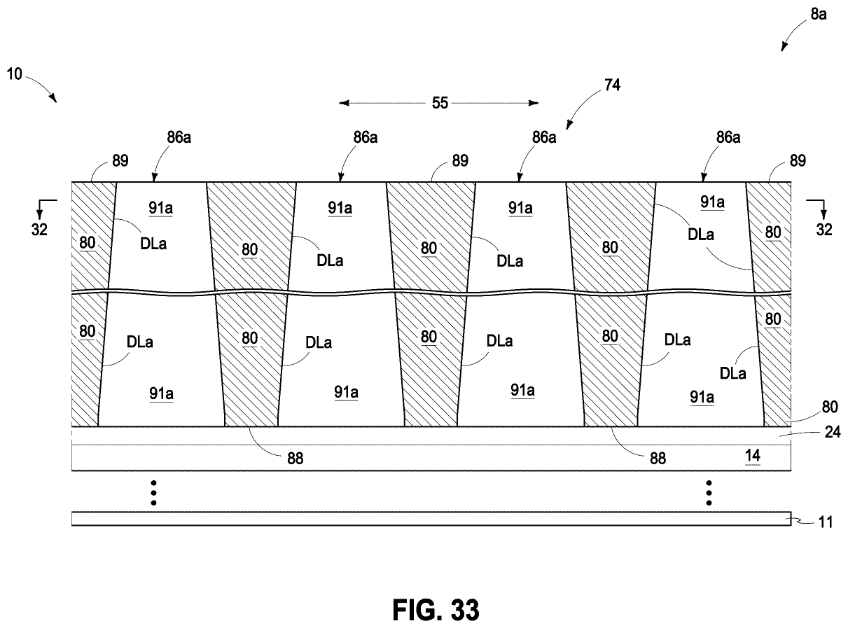

In one embodiment, the memory circuitry comprises the (b). In one embodiment, the memory circuitry comprises both of the (a) and the (b). In one embodiment, the memory circuitry comprises only one of the (a) and the (b). In one embodiment, the memory circuitry comprises the (a) and the individual digitlines in the first direction are wider at their tops bottoms than at their bottoms (e.g., FIGS. 30 and 33).

Any other attribute(s) or aspect(s) as shown and/or described herein with respect to other embodiments may be used.

Methods in accordance with embodiments of the invention may be easier to manufacture than prior methods. Structures in accordance with embodiments of the invention may have reduced parasitic capacitance between immediately-first-direction-adjacent digitlines.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication processor modems, modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### Conclusion

In some embodiments, a method used in forming memory circuitry comprising memory cells comprises forming vertically-alternating insulative tiers and memory-cell tiers. The memory cells individually comprise a horizontal transistor comprising a gate that is part of one of a plurality of horizontal conductive access lines that individually directly electrically couple together multiple of the gates of different ones of the horizontal transistors that are in the same memory-cell tier. The access lines extend horizontally along a first direction and are laterally spaced from one another in a second direction that is orthogonal to the first direction. Trenches extend through the vertically-alternating tiers. The trenches extend horizontally along the first direction and are spaced relative one another in the second direction. The trenches individually comprise conductive material and sacrificial material. The conductive material and the sacrificial material in individual of the trenches extend through the vertically-alternating tiers and extend horizontally in the first direction. The conductive material is on opposite second-direction sides of the individual trenches. The sacrificial material is laterally-between the conductive material that is on the second-direction sides of the individual trenches. Openings are formed through the sacrificial material in the individual trenches that are spaced relative one another in the first direction and laterally-expose the conductive material on the second-direction sides of the individual trenches. Through the openings, some of the conductive material on the second-direction sides of the individual trenches is removed to form pairs of digitlines from remaining of the conductive material. The pairs in the individual trenches are spaced from one another in the first direction. The digitlines in individual of the pairs are spaced from one another in the second direction on the opposite second-direction sides of the individual trenches in a horizontal cross-section. A frustum is formed in individual of the openings through the vertically-alternating tiers. The frustum has a vertically-elongated void-space therein. The sacrificial material is removed selectively relative to the frustum and replaces the sacrificial material with insulator material.

In some embodiments, a method used in forming memory circuitry comprising memory cells comprises forming vertically-alternating insulative tiers and memory-cell tiers. The memory cells individually comprise a horizontal transistor comprising a gate that is part of one of a plurality of horizontal conductive access lines that individually directly electrically couple together multiple of the gates of different ones of the horizontal transistors that are in the same memory-cell tier. The access lines extend horizontally along a first direction and are laterally spaced from one another in a second direction that is orthogonal to the first direction. Trenches extend through the vertically-alternating tiers. The trenches extend horizontally along the first direction and are spaced relative one another in the second direction. The trenches individually comprise conductive material and first sacrificial material. The conductive material and the first sacrificial material in individual of the trenches extend through the vertically-alternating tiers and extend horizontally in the first direction. The conductive material is on opposite second-direction sides of the individual trenches. The first sacrificial material is laterally-between the conductive material that is on the second-direction sides of the individual trenches. Openings are formed through the first sacrificial material in the individual trenches that are spaced relative one another in the first direction. Second sacrificial material is formed in the openings. The second sacrificial material is of different composition from that of the first sacrificial material. The first sacrificial material and some of the conductive material on the second-direction sides of the individual trenches are removed to form pairs of digitlines from remaining of the conductive material. The pairs in the individual trenches are spaced from one another in the first direction. The digitlines in individual of the pairs are spaced from one another in the second direction on the opposite second-direction sides of the individual trenches and have the second sacrificial material therebetween in a horizontal cross-section. A frustum is formed between immediately-first-direction-adjacent of the pairs in the individual trenches. The frustum has a vertically-elongated void-space therein. The second sacrificial material is removed selectively relative to the frustum and replaces the second sacrificial material with insulator material.

In some embodiments, memory circuitry comprising memory cells comprises vertically-alternating insulative tiers and memory-cell tiers. The memory cells individually comprise a horizontal transistor comprising a gate that is part of one of a plurality of horizontal conductive access lines that individually directly electrically couple together multiple of the gates of different ones of the horizontal transistors that are in the same memory-cell tier. The access lines extend horizontally along a first direction and are laterally spaced from one another in a second direction that is orthogonal to the first direction. Digitlines extend vertically through the vertically-alternating insulative tiers and memory-cell tiers in trenches that extend horizontally along the first direction. Individual source/drain regions of individual of the horizontal transistors that are in different memory-cell tiers are directly electrically coupled to individual of the digitlines. The digitlines comprise pairs thereof in individual of the trenches. The pairs in the individual trenches are spaced from one another in the first direction. The digitlines in individual of the pairs are spaced from one another in the second direction on opposite second-direction sides of the individual trenches in a horizontal cross-section. The memory circuitry comprises at least one of (a) and (b), where: (a): a vertically-elongated void-space in the individual trenches between immediately-first-direction-adjacent of the pairs; or (b): the individual digitlines in the first direction being wider at their bottoms than at their tops.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry comprising memory cells, comprising:
forming vertically-alternating insulative tiers and memory-cell tiers, the memory cells individually comprising a horizontal transistor comprising a gate that is part of one of a plurality of horizontal conductive access lines that individually directly electrically couple together multiple of the gates of different ones of the horizontal transistors that are in the same memory-cell tier, the access lines extending horizontally along a first direction and being laterally spaced from one another in a second direction that is orthogonal to the first direction;
trenches extending through the vertically-alternating tiers, the trenches extending horizontally along the first direction and being spaced relative one another in the second direction, the trenches individually comprising conductive material and sacrificial material, the conductive material and the sacrificial material in individual of the trenches extending through the vertically-alternating tiers and extending horizontally in the first direction, the conductive material being on opposite second-direction sides of the individual trenches, the sacrificial material being laterally-between the conductive material that is on the second-direction sides of the individual trenches;
forming openings through the sacrificial material in the individual trenches that are spaced relative one another in the first direction and laterally-expose the conductive material on the second-direction sides of the individual trenches;
through the openings, removing some of the conductive material on the second-direction sides of the individual trenches to form pairs of digitlines from remaining of the conductive material; the pairs in the individual trenches being spaced from one another in the first direction; the digitlines in individual of the pairs being spaced from one another in the second direction on the opposite second-direction sides of the individual trenches in a horizontal cross-section;
forming a frustum in individual of the openings through the vertically-alternating tiers, the frustum having a vertically-elongated void-space therein; and removing the sacrificial material selectively relative to the frustum and replacing the sacrificial material with insulator material.

2. The method of claim 1 wherein the frustum is insulative and remains in a finished-circuitry construction.

3. The method of claim 2 wherein insulative material of the frustum is of the same composition as the insulator material.

4. The method of claim 2 wherein insulative material of the frustum is of different composition from that of the insulator material.

5. The method of claim 1 comprising removing the frustum after the replacing of the sacrificial material with the insulator material.

6. The method of claim 5 wherein the frustum is insulative and insulative material of the insulative frustum is of the same composition as the insulator material, the removing comprising a timed non-selective etch of the insulative frustum relative to the insulator material that replaces the sacrificial material.

7. The method of claim 5 wherein the frustum is of different composition from that of the insulator material, the removing comprising a selective etch of the frustum relative to the insulator material that replaces the sacrificial material.

8. The method of claim 5 wherein the frustum is semiconductive.

9. The method of claim 5 wherein the frustum is conductive.

10. The method of claim 1 wherein individual of the digitlines in the first direction are wider at their bottoms than at their tops.

11. A method used in forming memory circuitry comprising memory cells, comprising:
forming vertically-alternating insulative tiers and memory-cell tiers, the memory cells individually comprising a horizontal transistor comprising a gate that is part of one of a plurality of horizontal conductive access lines that individually directly electrically couple together multiple of the gates of different ones of the horizontal transistors that are in the same memory-cell tier, the access lines extending horizontally along a first direction and being laterally spaced from one another in a second direction that is orthogonal to the first direction;
trenches extending through the vertically-alternating tiers, the trenches extending horizontally along the first direction and being spaced relative one another in the second direction, the trenches individually comprising conductive material and first sacrificial material, the conductive material and the first sacrificial material in individual of the trenches extending through the vertically-alternating tiers and extending horizontally in the first direction, the conductive material being on opposite second-direction sides of the individual trenches, the first sacrificial material being laterally-between the conductive material that is on the second-direction sides of the individual trenches;
forming openings through the first sacrificial material in the individual trenches that are spaced relative one another in the first direction;
forming second sacrificial material in the openings, the second sacrificial material being of different composition from that of the first sacrificial material;
removing the first sacrificial material and some of the conductive material on the second-direction sides of the individual trenches to form pairs of digitlines from remaining of the conductive material, the pairs in the individual trenches being spaced from one another in the first direction, the digitlines in individual of the pairs being spaced from one another in the second direction on the opposite second-direction sides of the individual trenches and having the second sacrificial material therebetween in a horizontal cross-section;
forming a frustum between immediately-first-direction-adjacent of the pairs in the individual trenches, the frustum having a vertically-elongated void-space therein; and
removing the second sacrificial material selectively relative to the frustum and replacing the second sacrificial material with insulator material.

12. The method of claim 11 wherein the frustum is insulative and remains in a finished-circuitry construction.

13. The method of claim 12 wherein insulative material of the frustum is of the same composition as the insulator material.

14. The method of claim 12 wherein insulative material of the frustum is of different composition from that of the insulator material.

15. The method of claim 11 comprising removing the frustum after the replacing of the second sacrificial material with the insulator material.

16. The method of claim 15 wherein the frustum is insulative and insulative material of the insulative frustum is of the same composition as the insulator material, the removing comprising a timed non-selective etch of the insulative frustum relative to the insulator material that replaces the second sacrificial material.

17. The method of claim 15 wherein the frustum is of different composition from that of the insulator material, the removing comprising a selective etch of the frustum relative to the insulator material that replaces the second sacrificial material.

18. The method of claim 15 wherein the frustum is semiconductive.

19. The method of claim 15 wherein the frustum is conductive.

20. Memory circuitry comprising memory cells, comprising:
vertically-alternating insulative tiers and memory-cell tiers, the memory cells individually comprising a horizontal transistor comprising a gate that is part of one of a plurality of horizontal conductive access lines that individually directly electrically couple together multiple of the gates of different ones of the horizontal transistors that are in the same memory-cell tier, the access lines extending horizontally along a first direction and being laterally spaced from one another in a second direction that is orthogonal to the first direction;
digitlines extending vertically through the vertically-alternating insulative tiers and memory-cell tiers in trenches that extend horizontally along the first direction, individual source/drain regions of individual of the horizontal transistors that are in different memory-cell tiers being directly electrically coupled to individual of the digitlines;
the digitlines comprising pairs thereof in individual of the trenches, the pairs in the individual trenches being spaced from one another in the first direction, the digitlines in individual of the pairs being spaced from one another in the second direction on opposite second-direction sides of the individual trenches in a horizontal cross-section; and
at least one of (a) and (b), where:
(a): a vertically-elongated void-space in the individual trenches between immediately-first-direction-adjacent of the pairs; or
(b): the individual digitlines in the first direction being wider at their bottoms than at their tops.
